(19) United States
(12) Patent Application Publication
(10) Pub. No.: US 2012/0298994 A1
(43) Pub. Date: Nov. 29, 2012

(54) SEMICONDUCTOR DEVICE

(75) Inventor: Kenichi SAWADA, Osaka (JP)

(73) Assignee: SUMITOMO ELECTRIC INDUSTRIES, LTD., Osaka-shi (JP)

(21) Appl. No.: 13/477,855

(22) Filed: May 22, 2012

Related U.S. Application Data
(60) Provisional application No. 61/489,474, filed on May 24, 2011.

(30) Foreign Application Priority Data
May 24, 2011 (JP) 2011-115652

(51) Int. Cl. H01L 23/48

(52) U.S. Cl. 257/48; 257/E23.01

(57) ABSTRACT

A semiconductor device according to an embodiment includes a plurality of unit cells having a FET structure, this semiconductor device having: a gate electrode wiring connected electrically to gate electrode of the FET structure of each unit cell; a gate electrode pad connected electrically to the gate electrode wiring and connecting each gate electrode to an external element; and a probe electrode pad that is connected electrically to the gate electrode wiring and with which an inspection probe comes into contact.

### CROSS-REFERENCE RELATED APPLICATIONS

This application claims priority to Provisional Application Ser. No. 61/489,474 filed on May 24, 2011 and claims the benefit of Japanese Patent Application No. 2011-115652, filed on May 24, 2011, all of which are incorporated herein by reference in their entirety.

### BACKGROUND

1. Field

Embodiments of present invention relate to a semiconductor device.

2. Description of the Related Art

A semiconductor device that includes a cell part having a parallel arrangement of a plurality of unit cells with a FET structure (e.g., MOSFET structure) has been known (see Japanese Unexamined Patent Application Publication No. 2006-100317, and pawaa MOSFET no katsuyo no kiso to jitsusai (Basics and Practices of Power MOSFET Applications) by Tamotsu Inaba (Feb. 1, 2010), CQ Publishing Co., Ltd., P. 22). This type semiconductor device is provided with a gate electrode pad that is conductive to each gate electrode. The gate electrodes included in the FET structure of unit cells are connected to an external element by connecting the gate electrode pad to an external element.

An inspection is performed on a semiconductor device in the production thereof. In the inspection, normally a probe used for the inspection is brought into contact with a gate electrode pad. In this inspection, the contact between the probe used for the inspection and the gate electrode pad imposes unnecessary stress onto the gate electrode pad that should originally be used to connect gate electrodes to an external element.

### SUMMARY

An object of the present invention is to provide a semiconductor device that is capable of reducing the stress imposed onto a gate electrode pad during an inspection of the semiconductor device.

A semiconductor device according to one aspect of the present invention includes a plurality of unit cells having a FET structure. This semiconductor device has a gate electrode wiring connected electrically to a gate electrode of the FET structure of each unit cell, a gate electrode pad connected electrically to the gate electrode wiring and connecting each gate electrode to an external element, and a probe electrode pad that is connected electrically to the gate electrode wiring and with which an inspection probe comes into contact.

In this aspect, the probe electrode pad is connected to the gate electrodes of the unit cells and the gate electrode pad by the gate electrode wiring. By bringing the inspection probe into contact with the probe electrode pad in place of the gate electrode pad, the semiconductor device can be inspected. Stress imposed onto the gate electrode pad can be reduced during the inspection of the semiconductor device.

A semiconductor device according to one embodiment may have a cell part and an outer circumferential part that surrounds the cell part and electrically protects the cell part. In this embodiment, the cell part may be configured by a parallel arrangement of the plurality of unit cells. The probe electrode pad may be provided on an outer rim part of the cell part and project from the cell part toward the outer circumferential part.

The cell part is configured by a parallel arrangement of the plurality of unit cells having the FET structure, and therefore functions as an operation region in the semiconductor device. In the embodiment described above, the area (or the size) of the cell part functioning as the operation region can be ensured even when the probe electrode pad is provided in addition to the gate electrode pad.

In one embodiment, the shape of the cell part in a planar view may be substantially a quadrangle. In this embodiment, the gate electrode wiring may be disposed along the outer rim part of the cell part. Moreover, the probe electrode pad may be provided in at least one of four corners configuring the outer rim part of the cell part.

In the embodiment where the shape of the cell part in a planar view is substantially a quadrangle and the gate electrode wiring is disposed along the outer rim part of the cell part, an electric field tends to concentrate in the corners of the cell part. In this case, the width of the outer circumferential part surrounding the cell part tends to increase. Therefore, in the embodiment where the probe electrode pad is disposed at the corner of the cell part, the region of the outer circumferential part can be utilized effectively and the probe electrode pad can be expanded.

Moreover, in one embodiment, the area of a front surface of the probe electrode pad is greater than that of a cross section of the inspection probe that is perpendicular to an axis thereof.

In this embodiment, when bringing the inspection probe into contact with the probe electrode pad, it is difficult for the inspection probe to come into contact with a region other than the probe electrode pad in the semiconductor device. For this reason, the semiconductor device can be inspected accurately by using the probe electrode pad.

In one embodiment, the semiconductor device has a plurality of probe electrode pads. In this case, without using the gate electrode pad, the semiconductor device can be inspected using, for example, a four-terminal method while bringing a plurality of inspection probes into contact with the plurality of probe electrode pads.

The present invention can provide a semiconductor device that is capable of reducing the stress imposed onto a gate electrode pad during an inspection of the semiconductor device.

### BRIEF DESCRIPTION OF THE DRAWINGS

FIG. 1 is a plan view of a semiconductor device according to an embodiment of the present invention;

FIG. 2 is a plan view of the semiconductor device shown in FIG. 1 without a passivation film provided on a front surface of the semiconductor device;

FIG. 3 is a drawing showing end surface structures taken along lines IIIa-IIIa, IIIb-IIIb, and IIIc-IIIc shown in FIG. 1;

FIG. 4 is a drawing showing an end surface structure taken along line VI-VI shown in FIG. 1;

FIG. 5 is a drawing showing an example of a sequence of steps of producing the semiconductor device shown in FIG. 1; and

FIG. 6 is a drawing showing a sequence of steps performed subsequent to the steps shown in FIG. 5.

### DETAILED DESCRIPTION

Embodiments of the present invention are described with reference to the drawings. In the descriptions of the drawings, the same reference numerals are used for indicating the same elements, and the overlapping explanations are omitted accordingly. The dimensional ratios shown in the drawings are schematic and do not necessarily correspond to specific dimensions set forth in the following description.

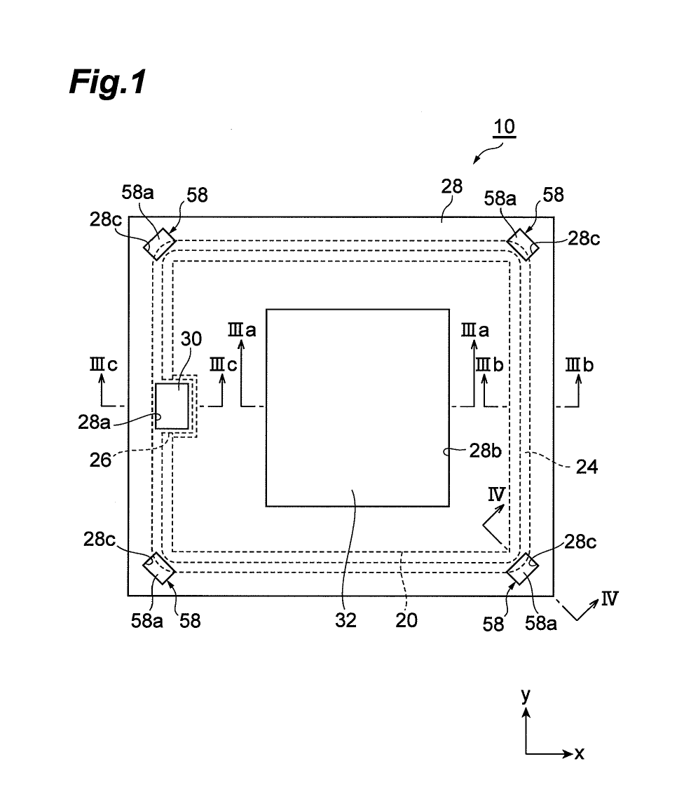

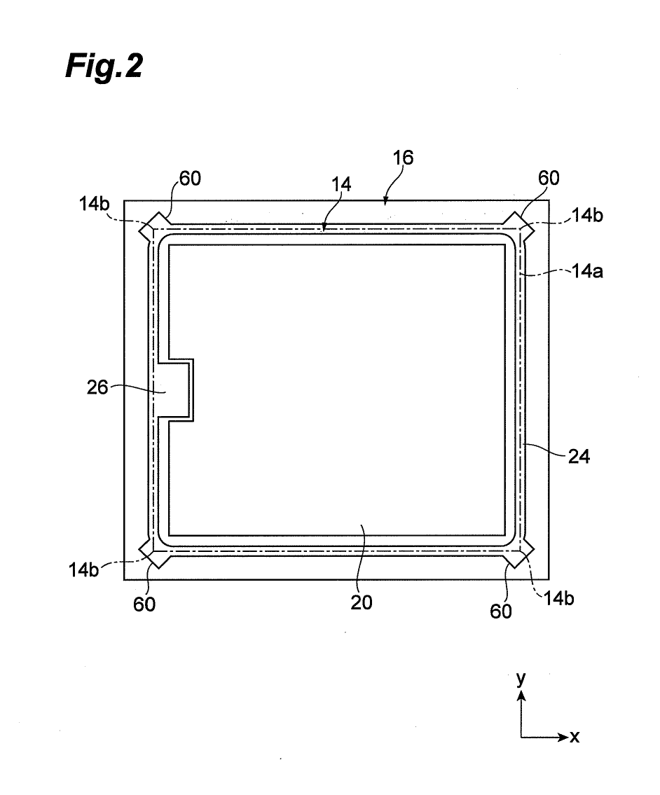

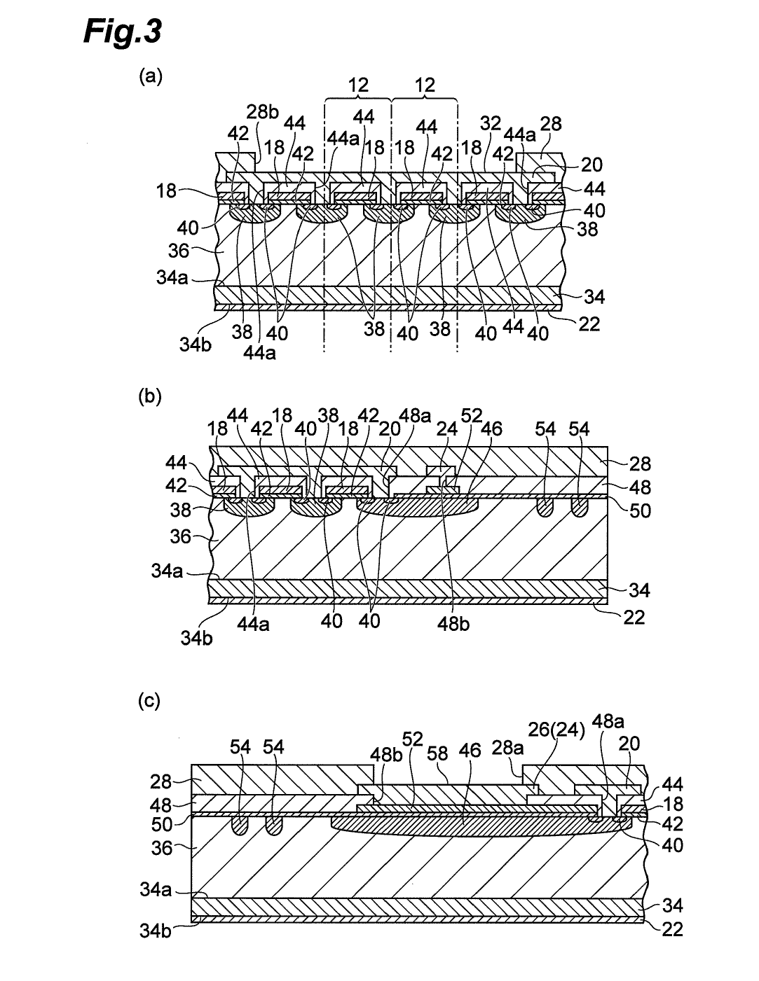

FIG. 1 is a plan view of a semiconductor device according to an embodiment of the present invention. FIG. 2 is a plan view of the semiconductor device shown in FIG. 1 without a passivation film provided on a front surface of the semiconductor device. (a) of FIG. 3, (b) of FIG. 3, and (c) of FIG. 3 are end views taken along lines IIIa-IIIa, IIIb-IIIb, and IIIc-IIIc shown in FIG. 1.

A schematic configuration of the semiconductor device 10 is described with reference to FIGS. 1 to 3. In the following description, two directions that are substantially perpendicular to a thickness direction of the semiconductor device 10 (a normal direction of a main surface 34a of a semiconductor substrate 34 described hereinafter) are referred to as “x-axis direction” and “y-axis direction,” as shown in FIGS. 1 and 2.

The semiconductor device 10 is a MOSFET (Metal-Oxide-Semiconductor Field-Effect Transistor) in which a compound semiconductor is used. Examples of the compound semiconductor adopted in the semiconductor device 10 include a wide-band-gap semiconductor such as SiC and GaN, and GaAs. The shape of the semiconductor device 10 in a planar view (the shape viewed in the thickness direction of the semiconductor device 10) is, for example, substantially a quadrangle, as shown in FIG. 1. Examples of the substantially quadrangle shape include a square and rectangles. When the shape of the semiconductor device 10 in a planar view is substantially a square, the length of each side of the semiconductor device 10 is, for example, 5 mm or shorter.

The semiconductor device 10 is a semiconductor chip that has a cell part 14 configured by a parallel arrangement of a plurality of unit cells 12 (see (a) of FIG. 3). The semiconductor device 10 has an outer circumferential part 16 (see FIG. 2) that surrounds the cell part 14 and electrically protects the cell part 14. The present embodiment describes the semiconductor device 10 having the outer circumferential part 16.

The shape of the cell part 14 in a planar view can be the same as that of the semiconductor device 10. In the description of the present embodiment, the shape of the cell part 14 in a planar view is substantially a square, as illustrated in FIG. 2. The length of each side of the cell part 14 is, for example, 20 μm or shorter.

The unit cells 12 have a vertical MOSFET structure. As shown in (a) of FIG. 3, the unit cells 12 that are adjacent to each other are arranged in parallel in a physically continuous manner. In this embodiment, the cell part 14 is an active part where main current flows through a channel region. In one embodiment, the cell part 14 can be configured by connecting the plurality of unit cells 12 in parallel in the form of an array, the unit cells 12 having an angular shape in a planar view. In another embodiment, the unit cells 12 can be arranged in stripes in a manner as to extend in one direction. In this case, the cell part 14 is configured by a parallel arrangement of the plurality of unit cells 12 in which each unit cell 12 is perpendicular to the direction in which the unit cells 12 extend.

Each of the unit cells 12 is defined based on a gate electrode 18. In the semiconductor device 10, a source electrode 20 and a drain electrode 22 are shared by the plurality of unit cells 12. More specifically, a part of the source electrode 20 on a front surface of the semiconductor device 10 and a part of the drain electrode 22 on a rear surface of the semiconductor device 10 function as a source electrode and drain electrode of each unit cell 12, respectively. However, the source electrode 20 and the drain electrode 22 may be provided in each unit cell 12.

On a front surface of the cell part 14, a gate electrode wiring 24 is formed along an outer rim part 14a (a rim part marked by a dashed line in FIG. 2) of the cell part 14. The gate electrode wiring 24 is disposed in a circular manner. In the present embodiment, since the shape of the cell part 14 in a planar view is substantially a square, the shape of the gate electrode wiring 24 in a planar view is also substantially a square. The gate electrode wiring 24 provided in the semiconductor device 10 is connected electrically to the gate electrode 18 of each of the unit cells 12. The gate electrode wiring 24 is a so-called “gate runner.” A first pad electrode 26 (see FIG. 2 and (c) of FIG. 3) is physically connected to a part of the gate electrode wiring 24. Because the gate electrode wiring 24 and the first pad electrode 26 have electrical conductivity, the gate electrode wiring 24 and the first pad electrode 26 are connected electrically to each other.

A passivation film 28 (see FIG. 1 and (a) to (c) of FIG. 3), serving as a protective film for covering the source electrode 20 and the gate electrode wiring 24, is formed on the front surface of the cell part 14 and the outer circumferential part 16. The front surface of the cell part 14 and the outer circumferential part 16 is protected by this passivation film 28. In the semiconductor device 10, an opening part 28a and an opening part 28b are formed in the passivation film 28 on the first pad electrode 26 and the source electrode 20, respectively. A region in the first pad electrode 26 that is exposed due to the presence of the opening part 28a functions as a gate electrode pad 30. A region in the source electrode 20 that is exposed due to the presence of the opening part 28b functions as a source electrode pad 32.

The configuration of the semiconductor device 10 is further described in detail with reference to (a) to (c) of FIG. 3. First of all, configurations common to the cell part 14 and the outer circumferential part 16 are described.

The semiconductor device 10 has the semiconductor substrate 34 of n-type conductivity (first conductivity type). The material of the semiconductor substrate 34 is, for example, a compound semiconductor. Examples of the compound semiconductor include a wide-band-gap semiconductor such as SiC and GaN, and GaAs, as described earlier. The thickness of the semiconductor substrate 34 is, for example, 400 μm. The drain electrode 22 is provided on a surface 34b (referred to as “rear surface” hereinafter), the opposite side of the main surface 34a of the semiconductor substrate 34. The drain electrode 22 is, for example, a metallic film such as a Ni film. An n-type drift layer 36 serving as an underlying semiconductor layer is provided on the main surface 34a of the semiconductor substrate 34. The material of the drift layer 36 can be, for example, the same as that of the semiconductor substrate 34. The concentration of the n-type dopant in the drift layer 36 is, for example, approximately 5×10¹⁶ cm⁻³. The thickness of the drift layer 36 is, for example, approximately 10 μm.

Next is described configurations of the cell part 14 and the outer circumferential part 16 on the semiconductor substrate 34. First, the configuration of the cell part 14 under the source electrode 20 is described by using, mainly, (a) of FIG. 3. A configuration in the vicinity of the outer rim part 14a of the cell part 14 will be described later.

A plurality of p-type (second conductivity type) semiconductor regions 38 as p-body regions are formed at intervals on a front layer part of the drift layer 36. The material of the p-type semiconductor regions 38 can be the same as that of the semiconductor substrate 34. The concentration of the p-type dopant in the p-type semiconductor regions 38 is, for example, approximately 5×10¹⁷ cm⁻³. The thickness (or the depth) of each p-type semiconductor region 38 is, for example, approximately 1.0 μm. When the shape of the unit cells 12 in a planar view is an angular shape, the p-type semiconductor regions 38 are formed in an island shape on the front layer part of the drift layer 36. However, when the unit cells 12 extend in one direction, the p-type semiconductor regions 38 can extend in one direction as well.

In each p-type semiconductor region 38, two n-type source regions 40 are formed with a space therebetween. The concentration of the n-type dopant in each source region 40 is, for example, approximately 1×10¹⁹ cm ⁻³. The thickness (or the depth) of each source region 40 is, for example, approximately 0.3 μm.

A gate insulator film 42 and each gate electrode 18 are stacked on a region between the adjacent p-type semiconductor regions 38 formed on the front surface of the drift layer 36. The gate insulator film 42 and the gate electrode 18 are disposed on the region between the adjacent p-type semiconductor regions 38, in a manner as to form a MOS structure in cooperation with the source regions 40 of each p-type semiconductor region 38. In the present embodiment, the gate insulator film 42 and the gate electrode 18 can be provided in each of the unit cells 12. The gate insulator film 42 is, for example, a silicon dioxide film. The thickness of the gate insulator film 42 is, for example, approximately 50 μm. The gate electrode 18 is, for example, a metallic film such as an Al film.

A raised part formed by the gate insulator film 42 and the gate electrode 18 is covered with an interlayer insulator film 44. The interlayer insulator film 44 is, for example, a silicon dioxide film. The source electrode 20 is provided on the interlayer insulator film 44. The source electrode 20 is, for example, a metallic film such as a Ni film. The thickness of the source electrode 20 is, for example, approximately 0.1 μm. A contact region 44a which penetrate the interlayer insulator film 44 in a thickness direction of the interlayer insulator film 44, such as a contact hole, is formed in the interlayer insulator film 44 so that the source regions 40 and the source electrode 20 come into electrical contact with each other.

In the configuration described above, the unit cells 12 have a double-diffused MOSFET structure, which is the vertical MOSFET structure. More specifically, in terms of each gate electrode 18, each of the unit cells 12 includes the semiconductor substrate 34, the drain electrode 22 provided on the rear surface 34b, the drift layer 36 provided on the main surface 34a, the p-type semiconductor regions 38 formed with a space therebetween on the front layer part of the drift layer 36, the source regions 40 formed in each p-type semiconductor region 38, the gate insulator film 42 and the gate electrode 18 that configure the MOS structure in cooperation with the source regions 40, and the source electrode 20 that is connected electrically to the source regions 40 but insulated from the gate electrode 18.

Next, mainly with reference to (b) of FIG. 3 and (c) of FIG. 3, a configuration of the outer rim part 14a of the cell part 14 where the gate electrode wiring 24 is formed is described.

The p-type semiconductor regions 38 as p-body regions, are formed on the front layer part of the drift layer 36, along the outer rim part 14a of the cell part 14. For the convenience of explanation, the p-type semiconductor regions 38 formed along the outer rim part 14a are referred to as “p-type semiconductor regions 46” hereinafter. In one embodiment, in order to achieve pressure-resistant properties of the semiconductor device 10, the p-type semiconductor regions 46 project outward from the cell part 14 toward the outer circumferential part 16. In an end part of each p-type semiconductor region 46 that is close to the center of the cell part 14, the source region 40 configuring a part of the unit cell 12 and the source region 40 configuring the MOS structure in cooperation with an insulator film 50 and gate wiring member 52 are formed with a space therebetween, the insulator film 50 and the gate wiring member 52 being described hereinafter.

The insulator film 50 covered with an interlayer insulator film 48 is provided on the p-type semiconductor region 46. The materials and thickness of the insulator film 50 and the interlayer insulator film 48 can be the same as those of the gate insulator film 42 and the interlayer insulator film 44. An end part of the interlayer insulator film 48 that is close to the center of the cell part 14 is covered with a part of the source electrode 20. A contact region 48a is pierced through the interlayer insulator film 48 in order to electrically connect the source regions 40 of the p-type semiconductor region 46 and the source electrode 20 to each other.

The conductive gate wiring member 52 that is provided along the outer rim part 14a of the cell part 14 is buried in the interlayer insulator film 48. The thickness and material of the gate wiring member 52 can be the same as those of the gate electrodes 18. The gate wiring member 52 is connected electrically to each gate electrode 18. An example of the electrical connection between the gate wiring member 52 and each gate electrode 18 is now described. Suppose that the gate wiring member 52 disposed along the outer rim part 14a is a primary gate wiring member (or a backbone gate wiring member). In this case, from the primary gate wiring member 52, a secondary gate wiring member is derived, and this secondary gate wiring member is spread over the inside of the cell part 14 in a manner as to be connected physically to each gate electrode 18. In this manner, the gate wring member 52 and each of the gate electrodes 18 can be electrically connected to each other. In this case, the secondary gate wiring member may be covered with or buried in an insulator film in a manner as to be insulated from the source electrode 20 and the source regions 40. Alternatively, in the case where the unit cells 12 extend in one direction, either end of the gate electrode 18 may be directly connected physically to the gate wiring member 52.

The gate electrode wiring 24 is provided on the interlayer insulator film 48, in a direction in which the gate wiring member 52 extends, which is, in other words, along the outer rim part 14a. The contact region 48b is pierced through the interlayer insulator film 48 on the gate electrode wiring 24. The gate electrode wiring 24 is connected electrically to the gate wiring member 52 via the contact region 48b. As a result, the gate electrode wiring 24 is connected electrically to the gate electrode 18 of each unit cell 12. An example of the gate electrode wiring 24 can be the same as that of the source electrode 20.

As shown in (c) of FIG. 3, the first pad electrode 26 is provided in a part of the gate electrode wiring 24, that is, for example, a part of a region within the substantially quadrangular gate electrode wiring 24 that extends in the y-axis direction as shown in FIG. 1. The first pad electrode 26 can be formed by forming a part of the gate electrode wiring 24 in a manner that the width thereof increases toward the center of the cell part 14. Beneath the first pad electrode 26, the p-type semiconductor region 46 and the gate wiring member 52 also project toward the center of the cell part 14.

The configuration of the outer circumferential part 16 is described with reference to (b) of FIG. 3 and (c) of FIG. 3. In the outer circumferential part 16, the insulator film 50 and the interlayer insulator film 48 are stacked sequentially on the drift layer 36. Here, the outer circumferential part 16 includes the insulator film 50 and the interlayer insulator film 48; however, it is only necessary that the outer circumferential part 16 include the drift layer 36. Allowing the outer circumferential part 16 to share the drift layer 36 with the cell part 14 can obtain a wider depletion layer in the case of inverse bias, accomplishing the pressure-resistant properties of the semiconductor device 10. In this case, the outer circumferential part 16 functions as an outer circumferential pressure-resistant part for ensuring the pressure-resistant properties.

As described above, each p-type semiconductor region 46 can project to the region of the outer circumferential part 16 that is close to the cell part 14. The projecting p-type semiconductor regions 46 allow the depletion layer to spread out more evenly in the case of inverse bias. Thus, ensuring the pressure-resistant properties of the semiconductor device 10 becomes more achievable. The drift layer 36 of the outer circumferential part 16 may be provided with trench-like p-type semiconductor regions 54 in order to further ensure the pressure-resistant properties of the semiconductor device 10. The p-type dopant concentration and the thickness of each p-type semiconductor region 54 can be the same as those of the p-type semiconductor regions 38.

As shown in (a) to (c) of FIG. 3, the front surface of the cell part 14 and the outer circumferential part 16 is covered with the passivation film 28. The opening part 28a is formed in the passivation film 28 on the first pad electrode 26. The region in the first pad electrode 26 that is exposed due to the presence of the opening part 28a is the gate electrode pad 30. The opening part 28b is formed in the passivation film 28 on the source electrode 20. The region in the source electrode 20 that is exposed due to the presence of the opening part 28b is the source electrode pad 32. The passivation film 28 is, for example, a SiN film. The thickness of the passivation film 28 is, for example, 10 μm.

In the semiconductor device 10 configured as described above, the unit cells 12 configuring the cell part 14 can be electrically connected to an external element (or a circuit) by electrically connecting the gate electrode pad 30, the source electrode pad 32, and the drain electrode 22 to an element (or a circuit) different from the semiconductor device 10.

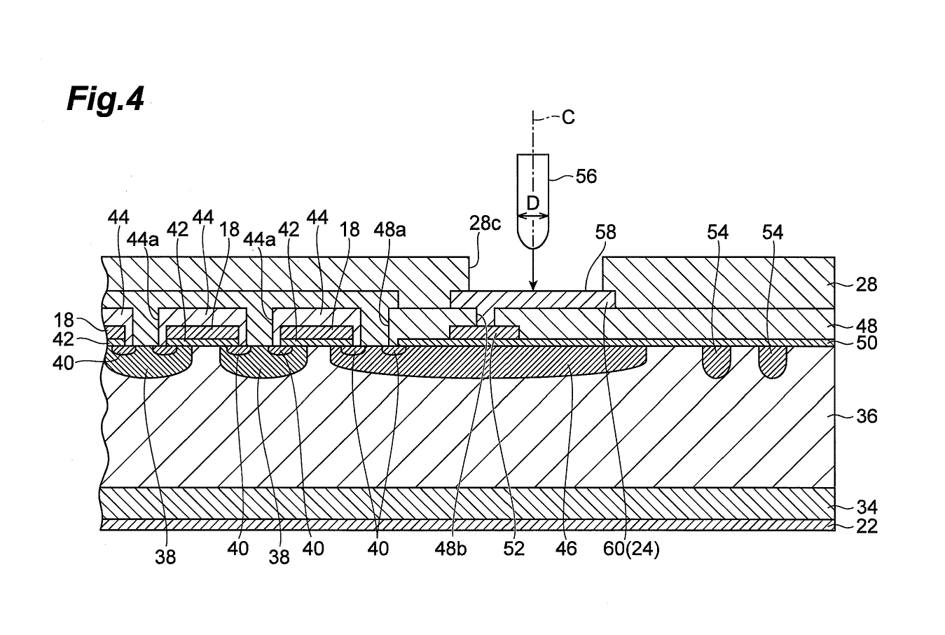

In addition to the gate electrode pad 30 and the source electrode pad 32, the semiconductor device 10 further has a probe electrode pad 58 with which an inspection probe 56 (see FIG. 4) is brought into contact during an inspection of the semiconductor device 10, as shown in FIG. 1. In one embodiment, the semiconductor device 10 can have the probe electrode pad 58 in each of corners 14b of the substantially quadrangular cell part 14, as shown in FIGS. 1 and 2. FIG. 1 illustrates a configuration in which the probe electrode pad 58 is disposed in each of the four corners 14b of the cell part 14. These probe electrode pads 58 project from the cell part 14 toward the outer circumferential part 16, as shown in FIG. 1.

The configuration of the semiconductor device 10 in terms of the positions where the probe electrode pads 58 are formed is described with reference to FIG. 4. FIG. 4 is a drawing schematically showing an end surface structure taken along line IV-IV shown in FIG. 1.

On the interlayer insulator film 48, second pad electrodes 60 connected electrically to the gate electrode wiring 24 are provided in the corners of the gate electrode wiring 24. As with the first pad electrode 26, the corners of the substantially quadrangular gate electrode wiring 24 and the regions in the vicinity thereof are formed to be wide, so that each of the second pad electrodes 60 can be formed. The passivation film 28 further has an opening part 28c on each of the second pad electrodes 60. A region in each second pad electrode 60 that is exposed due to the presence of the opening part 28c is each probe electrode pad 58.

The shape of the probe electrode pads 58 in a planar view is, for example, substantially a quadrangle, substantially a fan shape, or a circle. Examples of the substantially quadrangle shape include substantially rectangular shapes and a substantially square shape. The size of the probe electrode pads 58 can be controlled in a manner that the inspection probe 56 does not come into contact with a circumferential wall of each opening part 28c when coming into contact with each probe electrode pad 58. In order for the inspection probe 56 not to come into contact with the circumferential wall of opening part 28c, the area of a front surface 58a of each probe electrode pad 58 or the area of each opening part 28c is greater than the cross-sectional area of the inspection probe 56, which is the area of the cross section of the probe 56 that is perpendicular to an axis C. In other words, the area of each probe electrode pad 58 is greater than the cross-sectional area of the inspection probe 56 defined based on a diameter D of the inspection probe 56.

The diameter D is the diameter of an end part on the opposite side of a tip end part of the probe 56. However, when the tip end part of the probe 56 is tapered or curved as shown in FIG. 4, the diameter D may be the diameter at a position that is located near the other end of the probe 56 from the tip end part of the probe 56 by the thickness of the passivation film 28.

Because the inspection probe 56 does not come into contact with the circumferential wall of each opening part 28c, in one embodiment the length of the sides defining each probe electrode pad 58 can be at least 1.1 times the diameter D of the probe 56. As along as the length of the sides defining the probe electrode pad 58 is in this range, a certain space (margin) is obtained between the probe 56 and the circumferential wall of the opening part 28c. For this reason, the probe 56 cannot come into contact with the opening part 28c easily. More specifically, when the shape of the probe electrode pad 58 is substantially a rectangle as shown in FIG. 1 and the diameter D is 0.027 mm, the short sides of the probe electrode pad 58 (the length in a direction along line IIIc-IIIc shown in FIG. 1) is 0.03 mm or longer. When the probe electrode pad 58 is in a circular shape, the diameter of the opening part 28c may satisfy the range described above. The upper limit of the length of the probe electrode pad 58 may be determined according to the size of the outer circumferential part 16 and is, for example, not more than 1.5 times the diameter D.

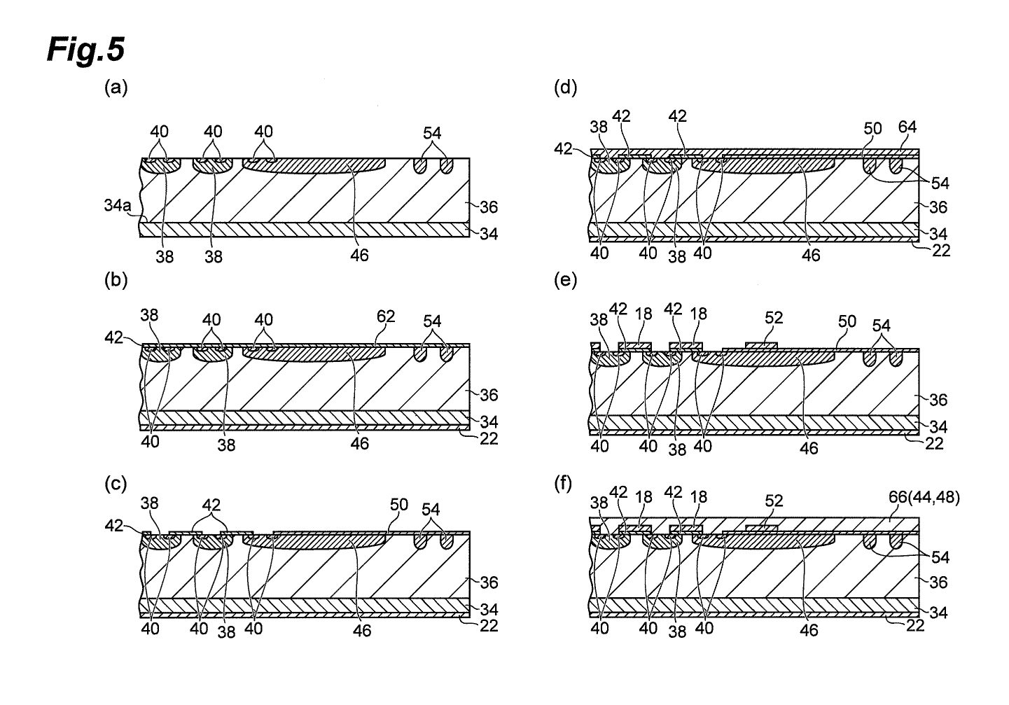

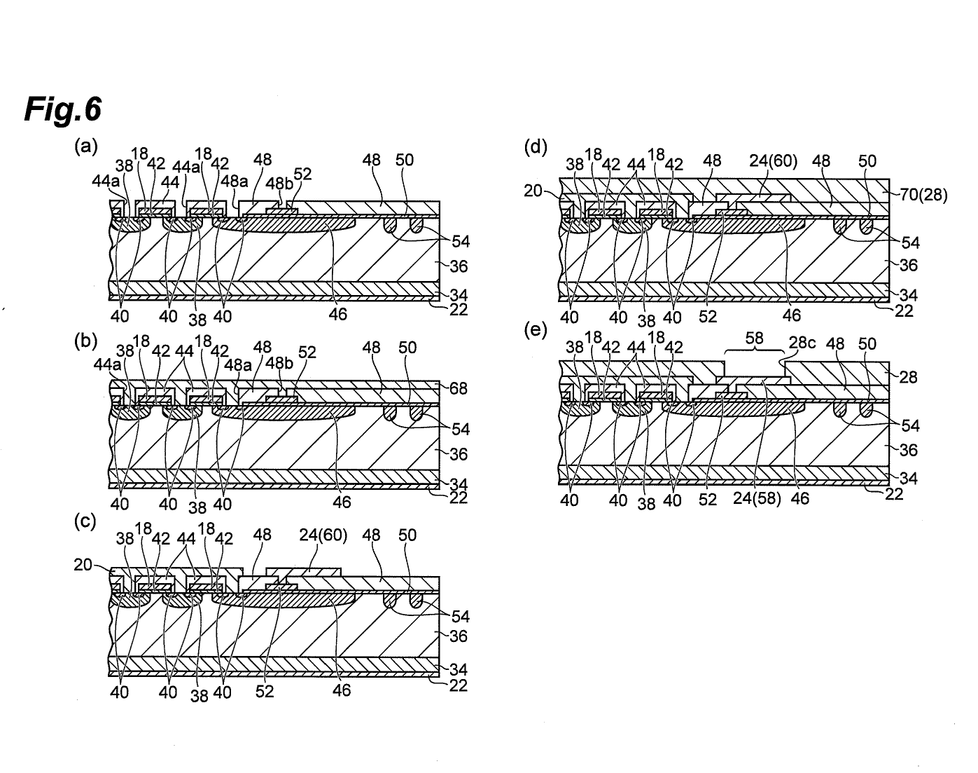

An example of a method for producing the semiconductor device 10 having the probe electrode pads 58 is described with reference to (a) to (f) of FIG. 5 and (a) to (e) of FIG. 6. Hereinafter, the method for producing the semiconductor device 10 is described while specifically illustrating the steps of forming each probe electrode pad 58. (a) to (f) of FIG. 5 and (a) to (e) of FIG. 6 show sequences of steps of producing the semiconductor device 10. (a) to (f) of FIG. 5 and (a) to (e) of FIG. 6 mainly show the steps of producing a section of the semiconductor device 10 that is near the region where each probe electrode pad 58 is formed.

As shown in (a) of FIG. 5, after forming the drift layer 36 on the main surface 34a of the semiconductor substrate 34 composed of an n-type SiC substrate, the p-type semiconductor regions 38, 46 and the source regions 40 are formed on the front layer part of the drift layer 36. In the case of forming the p-type semiconductor regions 54, the p-type semiconductor regions 54 are formed together with the p-type semiconductor regions 38 and the like. An embodiment with the p-type semiconductor regions 54 is described hereinafter. More specifically, the drift layer 36 is formed on the main surface 34a by using the CVD epitaxial growth method with in-situ doping. In the case of forming the drift layer 36 using the epitaxial growth method in this manner, the drift layer 36 is an epitaxial growth layer. Concave parts for the p-type semiconductor regions 38, 46, and 54 are formed in predetermined positions on the drift layer 36 by means of RIE (Reactive Ion Etching) or the like. Thereafter, the p-type semiconductor regions 38, 46, and 54 are epitaxially grown on the bottom surfaces and the side surfaces of the concave parts by using the CVD epitaxial growth method with in-situ doping. In so doing, the p-type semiconductor regions is embedding selective growth regions. The plurality of source regions 40 are formed by implanting ions into the p-type semiconductor regions 38, 46 using an implantation mask.

Subsequently, as shown in (b) of FIG. 5, a silicon dioxide film 62 is formed on the drift layer 36 as an insulator film by using, for example, a CVD method. Thereafter, the drain electrode 22 composed of a Ni film is formed on the rear surface 34b by using a deposition method or a sputtering method.

Next, as shown in (c) of FIG. 5, the gate insulator film 42 and the insulator film 50 are formed by performing patterning on the silicon dioxide film 62. Subsequently, as shown in (d) of FIG. 5, an Al film 64 is formed on the semiconductor substrate 34 by using, for example, the CVD method. The gate electrodes 18 and the gate wiring member 52 are formed as shown in (e) of FIG. 5 by performing patterning on the Al film 64. In a region located immediately below the first pad electrode 26, the gate wiring member 52 is formed in a manner that the width thereof increases toward the inside of the cell part 14, as shown in (c) of FIG. 3. Thereafter, as shown in (f) of FIG. 5, the gate electrodes 18 and the gate wiring member 52 are buried by further forming a silicon dioxide film 66 for the interlayer insulator film 44, 48 on the semiconductor substrate 34 by using, for example, the CVD method.

Subsequently, as shown in (a) of FIG. 6, in order to ensure the electrical contact between each source region 40 and the source electrode 20 and the electrical contact between the gate wiring member 52 and the gate electrode wiring 24, the contact regions 44a, 48a, and 48b are formed on the silicon dioxide film 66 to obtain the interlayer insulator film 44, 48. The contact regions 44a, 48a, and 48b can be formed by etching or the like.

As shown in (b) of FIG. 6, by using, for example, the CVD method, a Ni film 68 is formed on the semiconductor substrate 34 that has the silicon dioxide film 66 (interlayer insulator film 44, 48) having the contact regions 44a, 48a, and 48b formed thereon. The source electrode 20 and the gate electrode wiring 24 are formed by performing patterning on the Ni film 68, as shown in (c) of FIG. 6. In so doing, the second pad electrode 60 can be obtained by expanding the size of the gate electrode wiring 24 toward the outer circumferential part 16 on the corners 14b of the cell part 14. Here, the contact between the Ni configuring the source electrode 20 and the drain electrode 22 and the SiC configuring the source regions 40 and the semiconductor substrate 34 is changed from a Schottky contact to an ohmic contact by thermally treating the semiconductor substrate 34.

As shown in (d) of FIG. 6, using, for example, the CVD method, a SiN film 70 is formed on the semiconductor substrate 34 on which the source electrode 20 is formed. This SiN film 70 corresponds to the passivation film 28. The probe electrode pad 58 is formed, as shown in (e) of FIG. 6, by forming the opening 28c on the passivation film 28 by means of etching or the like. In so doing, the gate electrode pad 30 and the source electrode pad 32 are formed by forming the opening parts 28a, 28b on the passivation film 28.

The above has described some of the materials of the semiconductor substrate 34, the gate electrodes 18, the source electrode 20, and the drain electrode 22, and the method for forming these films, but the materials of the components configuring the semiconductor device 10 and the methods for forming these films are not limited to the ones illustrated above.

In addition to the gate electrode pad 30, the semiconductor device 10 described above has the probe electrode pads 58 used for inspecting the semiconductor device 10. The probe electrode pads 58 are connected electrically to the gate electrodes 18 and the gate electrode pad 30 via the gate electrode wiring 24. Therefore, the semiconductor device 10 can be inspected, by bringing the inspection probes 56 into contact with not the gate electrode pad 30 but the probe electrode pads 58.

Because the semiconductor device 10 is inspected using the probe electrode pads 58, the gate electrode pad 30 can be used, not for the inspection using the inspection probe, but for externally connecting the gate electrodes by means of wire bonding or the like. As a result, the gate electrode pad 30 can be used in optimal condition when creating the external connection, without imposing unnecessary stress onto the gate electrode pad 30 at the time of the inspection. Since no stress is imposed on the gate electrode pad 30 at the time of the inspection on the semiconductor device 10, the size of the gate electrode pad 30 can be made smaller, increasing the current rating of the semiconductor device 10.

Moreover, because the possibility of stress being imposed onto the gate electrode pad 30 at the time of the inspection no longer needs to be considered, it is not necessary to make the gate electrode pad 30 and the gate electrodes 18 thicker to reduce the effects of stress. As a result, the time required to produce the semiconductor device 10 can be reduced more compared to when making the gate electrode pad 30 thicker to reduce the impacts of stress thereon.

In the embodiment shown in FIG. 1 in which the semiconductor device 10 has the outer circumferential part 16 surrounding the cell part 14, the probe electrode pads 58 can be disposed on the outer rim part 14a of the cell part 14, in a manner as to project toward the outer circumferential part 16, in order to ensure the pressure-resistant properties. In this case, even with the probe electrode pads 58 provided in addition to the gate electrode pad 30, the area of the cell part 14 functioning as the active part can be maintained, the active part being a main operation region of the semiconductor device 10. As a result, the operational performance of the semiconductor device 10 can be ensured. Because the region of the outer circumferential part 16 for ensuring the pressure-resistant properties is used, it is not necessary to secure an additional region for allowing the probe electrode pads 58 to project outward from the cell part 14. In recent years, a chip size reduction is called for in the semiconductor device 10 such as semiconductor chip, while an increase in the size thereof is difficult to achieve on the grounds of crystal defects if the compound semiconductor is used. Therefore, the embodiment shown in FIG. 1, in which the semiconductor device 10 has the outer circumferential part 16 and the probe electrode pads 58 project toward the outer circumferential part 16, contributes to reduction in size of the semiconductor device 10 (e.g., reduction into a size in which each side of the chip is 5 mm or shorter), and becomes more effective when the compound semiconductor is employed in the semiconductor device 10.

When the shape of the cell part 14 in a planar view is, for example, a square or other substantially quadrangular shape and the gate electrode wiring 24 is disposed along the outer rim part 14a, an electric field tends to concentrate on each corner 14b of the cell part 14, causing insulation breakdown. This is noticeable in a power MOSFET that uses SiC or GaN. Thus, when the outer circumferential part 16 is provided in order to ensure the pressure-resistant properties as shown in FIG. 1, the width of the outer circumferential part 16 at each corner 14b of the cell part 14 (e.g., the width of the outer circumferential part 16 along the line IIIc-IIIc shown in FIG. 1) is wider than, for example, the width of the outer circumferential part 16 at the position marked by the line IIIb-IIIb shown in FIG. 1. As a result, placing the probe electrode pads 58 at the corners 14b of the cell part 14 can easily spread the probe electrode pads 58 toward the outer circumferential part 16. In this embodiment, since the wider regions are used in the outer circumferential part 16, larger probe electrode pads 58 can be formed. This can prevent, more reliably, each inspection probe 56 and each opening part 28c from coming into contact with each other during the inspection, improving the accuracy of inspecting the semiconductor device 10.

Furthermore, in the embodiment shown in FIG. 1 in which the semiconductor device 10 has two or more (four, in FIG. 1) of the probe electrode pads 58, the semiconductor device 10 can be inspected using the two probe electrode pads 58 without using the gate electrode pad 30, even when a four-terminal method is adopted as a method for inspecting the semiconductor device 10. Thus, the semiconductor device 10 can be inspected more accurately without exerting stress on the gate electrode pad 30 during inspection.

The above has described the embodiments of the present invention; however, the present invention is not limited thereto, and various modifications can be made without departing from the scope of the present invention. For instance, the unit cells 12 of the semiconductor device 10 may have the FET structure. Therefore, the MOSFET structure of the unit cells may be not only the vertical MOSFET structure but also a horizontal MOSFET structure. In addition, each of the unit cells 12 may be a JFET (junction gate field-effect transistor). The FET structure of the unit cells 12 may be not only of the n-channel type but also the p-channel type. Moreover, the probe electrode pads 58 may be provided in addition to the gate electrode pad 30 in the semiconductor device 10 and connected electrically to the gate electrode wiring 24. For example, the probe electrode pads 58 may be provided at positions other than the corners 14b of the cell part 14. In addition, one to three or five or more of the probe electrode pads 58 may be provided.

What is claimed is:

1. A semiconductor device that includes a plurality of unit cells having a FET structure,
the device comprising:
a gate electrode wiring connected electrically to a gate electrode of the FET structure of each unit cell;
a gate electrode pad connected electrically to the gate electrode wiring and connecting each gate electrode to an external element; and
a probe electrode pad that is connected electrically to the gate electrode wiring and with which an inspection probe comes into contact.

2. The semiconductor device according to claim 1, further comprising:
a cell part; and
an outer circumferential part that surrounds the cell part and electrically protects the cell part, wherein
the cell part is configured by a parallel arrangement of the plurality of unit cells, and
the probe electrode pad is provided on an outer rim part of the cell part and projects from the cell part toward the outer circumferential part.

3. The semiconductor device according to claim 2, wherein
the shape of the cell part in a planar view is substantially a quadrangle,
the gate electrode wiring is disposed along the outer rim part of the cell part, and
the probe electrode pad is provided in at least one of four corners of the cell part.

4. The semiconductor device according to claim 1, wherein the area of a front surface of the probe electrode pad is greater than that of a cross section of the inspection probe that is perpendicular to an axis thereof.

5. The semiconductor device according to claim 1, wherein the probe electrode pad is provided in plurality.
